(19) United States
(12) Patent Application Publication
(10) Pub. No.: US 2009/0140365 A1
(43) Pub. Date: Jun. 4, 2009

(54) Image sensor with back-side illuminated photoelectric converters

(76) Inventors: Yun-Ki Lee, Seoul (KR); Byung-Jun Park, Yongin-si (KR)

Correspondence Address: LAW OFFICE OF MONICA H CHOI, P O BOX 3424, DUBLIN, OH, 430160204, US

(21) Appl. No.: 12/287,068

(22) Filed: Oct. 6, 2008

(30) Foreign Application Priority Data
Oct. 5, 2007 (KR) 10-2007-0100436

(51) Int. Cl. H01L 31/101

(52) U.S. Cl. 257/460; 257/E31.054

(57) ABSTRACT

An image sensor includes a circuit substrate, a plurality of isolation regions, a plurality of photoelectric converters, and an insulation layer. The isolation regions are formed in a pixel region having the photoelectric converters formed therein with each photoelectric converter being electrically isolated by the isolation regions. The insulation layer is formed in a pad region with a substantially same depth as the isolation regions. The isolation region and the insulation layer are simultaneously formed for efficient fabrication of the image sensor.

This application claims priority under 35 USC § 119 to Korean Patent Application No. 10-2007-0100436, filed on Oct. 5, 2007 in the Korean Intellectual Property Office, the disclosure of which is incorporated herein in its entirety by reference.

### BACKGROUND OF THE INVENTION

1. Field of the Invention

The present invention relates generally to image sensors and a method of fabricating the same, and more particularly, to an image sensor with back-side illuminated photoelectric converters fabricated in a pixel region and with a pad formed in a pad region.

2. Background of the Invention

Image sensors convert images into electrical signals. With the recent development of the computer and communications industries, image sensors with enhanced performance are in increasing demand for use in various devices such as digital cameras, camcorders, PCs, game devices, security cameras, micro-cameras for medical use, and robots.

In an image sensor, incident light passes through a microlens formed over multi-layered wiring to then reach a photoelectric converter. However, the amount of light actually reaching the photoelectric converter may not be sufficient because of obstruction of light caused by the multi-layered wiring. That is, the multi-layered wiring reduces an aperture ratio with respect to the photoelectric converter. Thus, the amount of the light reaching the photoelectric converter is noticeably reduced resulting in decreased sensitivity of the photoelectric converter.

Accordingly, a back-side illuminated image sensor has been proposed with light being irradiated toward a back-side of a semiconductor substrate having photoelectric converters formed therein with wiring formed over a front-side of the substrate. Thus with the back-side illuminated image sensor, an effective aperture ratio may be increased without obstruction of light by the multi-layered wiring resulting in improved sensitivity of the image sensor.

### SUMMARY OF THE INVENTION

According to an aspect of the present invention, an image sensor includes a circuit substrate, a plurality of isolation regions, a plurality of photoelectric converters, and an insulation layer. The circuit substrate has a pixel region and a pad region, and the plurality of isolation regions are formed in the pixel region. The photoelectric converters are formed in the pixel region with each photoelectric converter being electrically isolated by the plurality of isolation regions. The insulation layer is formed in the pad region, with the plurality of isolation regions and the insulation layer extending into the circuit substrate with a substantially same depth.

In an embodiment of the present invention, the image sensor also includes a support substrate disposed to face a front-side of the circuit substrate, with the photoelectric converters being formed into the front-side of the circuit substrate.

In another embodiment of the present invention, the image sensor further includes a plurality of interconnects and a plurality of dielectric layers disposed between the front-side of the circuit substrate and the support substrate.

In a further embodiment of the present invention, the image sensor includes an opening, a conductive contact, and a conductive pad. The opening is formed through a central portion of the circuit substrate surrounded by the insulation layer and through a first dielectric layer, to abut a first layer interconnect. The conductive contact is formed at walls of the opening, and the conductive pad is formed over a back-side of the circuit substrate and is connected to the conductive contact.

In an embodiment of the present invention, the isolation regions and the opening become narrower from the front-side to the back-side of the circuit substrate.

In another embodiment of the present invention, the insulation layer surrounds at least a portion of the opening. In that case, one of the dielectric layers surrounds at least a remaining portion of the opening not surrounded by the insulation layer.

In a further embodiment of the present invention, the image sensor includes a substrate material of the circuit substrate disposed between the conductive contact and the insulation layer.

In another embodiment of the present invention, the isolation regions and the insulation layer extend completely through the circuit substrate.

In a further embodiment of the present invention, each photoelectric converter is a pinned photodiode formed from a front-side of the circuit substrate.

In another aspect of the present invention, an image sensor includes a circuit substrate, a plurality of isolation regions, a plurality of photoelectric converters, an opening, an insulation layer, and a conductive contact. The circuit substrate has a pixel region and a pad region, and the plurality of isolation regions are formed in the pixel region. The plurality of photoelectric converters are formed in the pixel region, with each photoelectric converter being electrically isolated by the plurality of isolation regions. The opening is formed through the circuit substrate in the pad region.

The insulation layer surrounds at least a portion of the opening in the pad region. The conductive contact is formed at walls of the opening. The substrate material of the circuit substrate is disposed between the conductive contact and the insulation layer. In addition, a support substrate is disposed to face a front-side of the circuit substrate, and the photoelectric converters are formed into the front-side of the circuit substrate.

In this manner, the isolation regions and the insulation layer are formed simultaneously for simplifying fabrication of the image sensor. In addition, the back-side of the circuit substrate is irradiated such that the photoelectric converters receive light without obstruction of light by the interconnects formed on the front-side. Thus, the sensitivity of the image sensor is enhanced with increased aperture ratio.

### BRIEF DESCRIPTION OF THE DRAWINGS

The above and other features and advantages of the present invention will become more apparent when described in detailed exemplary embodiments thereof with reference to the attached drawings in which:

FIG. 1 is a block diagram of an image sensor, according to an embodiment of the present invention;

FIG. 2 illustrates a lay-out of an image sensor as an integrated circuit chip, according to an embodiment of the present invention;

FIG. 3A is a circuit diagram of an active pixel sensor (APS) array in an image sensor, according to an embodiment of the present invention;

FIG. 3B is an enlarged layout view of an example area “a” in a pixel region of the image sensor of FIG. 2, according to an embodiment of the present invention;

FIG. 4 is an enlarged layout view of an example area “b” in a pad region of the image sensor of FIG. 2, according to an embodiment of the present invention;

FIG. 5 is a cross-sectional view of the image sensor taken along line I-I′ of FIG. 3B and line II-II′ of FIG. 4, according to an embodiment of the present invention;

FIGS. 6, 7, 8, 9, 10, 11, and 12 are cross-sectional views along line I-I′ of FIG. 3B and line II-II′ of FIG. 4 during fabrication of the image sensor of FIG. 5, according to an embodiment of the present invention;

FIGS. 13, 14, and 15 are cross-sectional views along line I-I′ of FIG. 3B and line II-II′ of FIG. 4 of the image sensor according to alternative embodiments of the present invention; and

FIG. 16 is a block diagram of a processor-based system including a CMOS image sensor implemented similarly to FIGS. 2, 3B, 4, 5, 13, 14, and/or 15 according to an embodiment of the present invention.

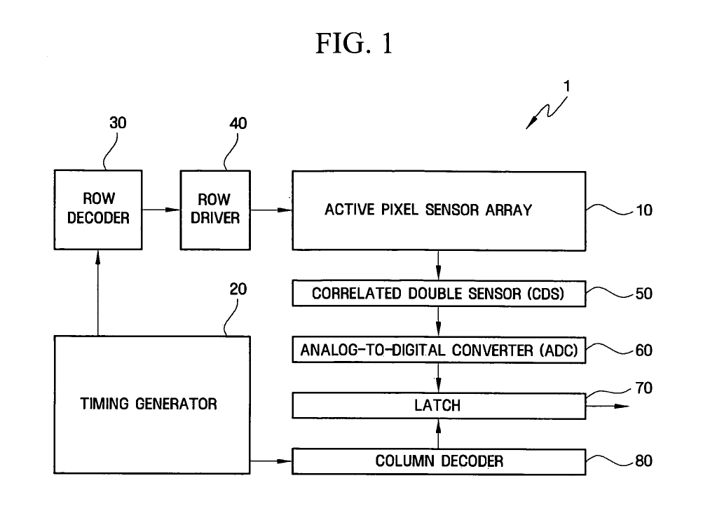

The figures referred to herein are drawn for clarity of illustration and are not necessarily drawn to scale. Elements having the same reference number in FIGS. 1, 2, 3A, 3B, 4, 5, 6, 7, 8, 9, 10, 11, 12, 13, 14, 15, and 16 refer to elements having similar structure and/or function.

### DETAILED DESCRIPTION OF THE INVENTION

When an element is referred to as being “connected” or “coupled” to another element herein, the element may be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Image sensors according to embodiments of the present invention may be a charge coupled device (CCD) image sensor or a complementary metal oxide semiconductor (CMOS) image sensor. The CCD image sensor typically has less noise and better image quality than the CMOS image sensor. However, the CCD image sensor requires a high voltage and is expensive to manufacture.

The CMOS image sensor is easy to operate and may be implemented using various scanning methods. A signal-processing circuit may be integrated with the image sensor on a single chip for the CMOS image sensor resulting in smaller products. In addition, the manufacturing cost may be reduced using CMOS manufacturing technology. Further, with very low power consumption, the CMOS image sensor is easily applied in products with limited battery capacity.

In light of such features of the CMOS image sensor, the present invention is described with reference to the CMOS image sensor. However, the present invention may also be practiced with same technical spirit in a CCD image sensor.

FIG. 1 is a block diagram of an image sensor 1 that may be a CMOS image sensor for example according to an example embodiment of the present invention. The image sensor 1 includes an active pixel sensor (APS) array 10, a timing generator 20, a row decoder 30, a row driver 40, a correlated double sampler (CDS) 50, an analog-to-digital converter (ADC) 60, a latch 70, and a column decoder 80.

The APS array 10 includes a plurality of unit pixels arranged in two dimensions of rows and columns. The unit pixels convert an optical image into electrical signals. The APS array 10 operates in response to a plurality of driving signals such as a pixel selection signal (ROW), a reset signal (RST), and first and second charge transmission signals (TG1 and TG2) received from the row driver 40. The APS array 10 provides the resulting electrical signals to the CDS 50 via vertical signal lines.

The timing generator 20 provides a timing signal and a control signal to the row decoder 30 and the column decoder 80. The row driver 40 provides the driving signals to operate the unit pixels of the APS array 10 according to a decoding result therein. Generally, when the unit pixels are arranged in a matrix form, a respective driving signal is provided for each row. The CDS 50 receives the electrical signals from the APS array 10 via the vertical signal lines for performing holding and sampling.

In detail, the CDS 50 double samples a reference voltage level (hereinafter, referred to as a “noise level”) and an image voltage level (hereinafter, referred to as a “signal level”) generated from sensing an image. The CDS 50 generates a differential level corresponding to a difference between the noise level and the signal level.

The ADC 60 converts an analog signal corresponding to the differential level into a digital signal. The latch 70 latches the digital signal and sequentially outputs the latched signal to an image signal processor (not shown) according to a decoding result of the column decoder 80.

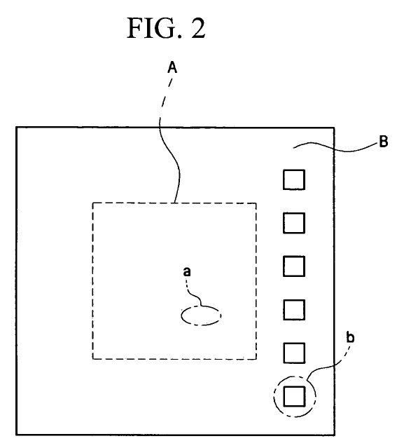

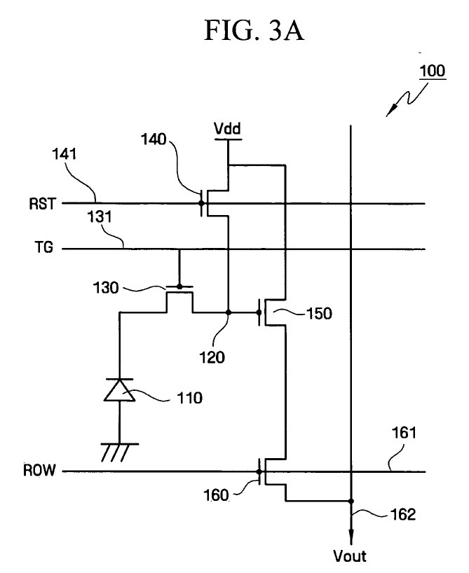

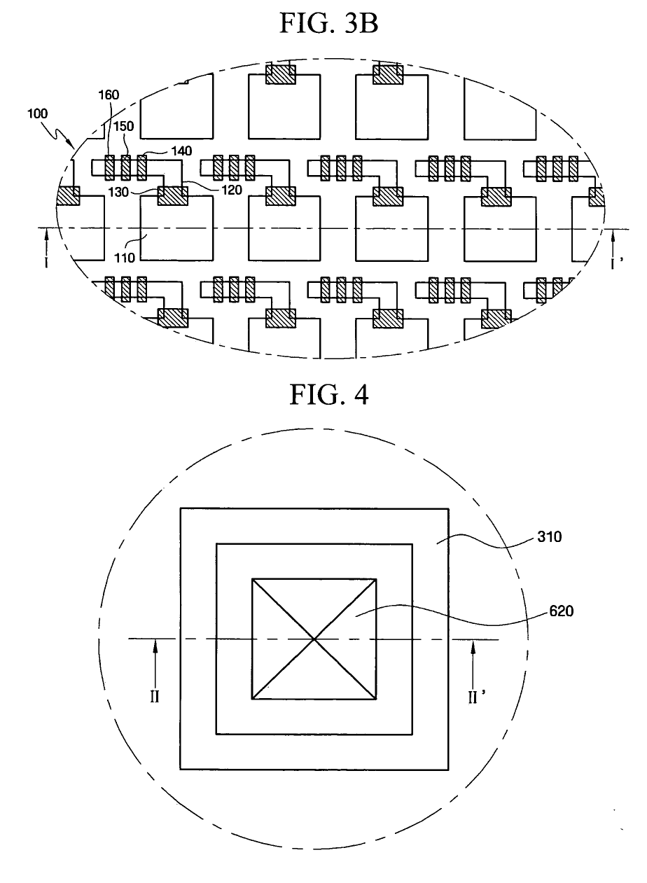

FIG. 2 illustrates a lay-out of an image sensor as an integrated circuit chip, according to an embodiment of the present invention. FIG. 3A is a circuit diagram of an active pixel sensor (APS) array including a pixel unit in an image sensor, according to an embodiment of the present invention. FIG. 3B is an enlarged layout view of an example area “a” in a pixel region of the image sensor of FIG. 2, according to an embodiment of the present invention.

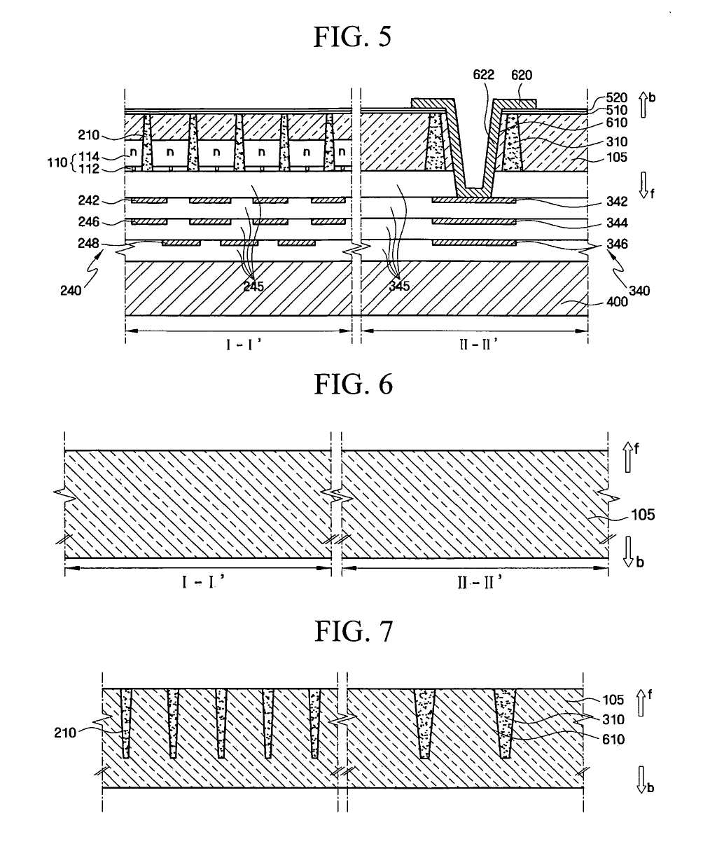

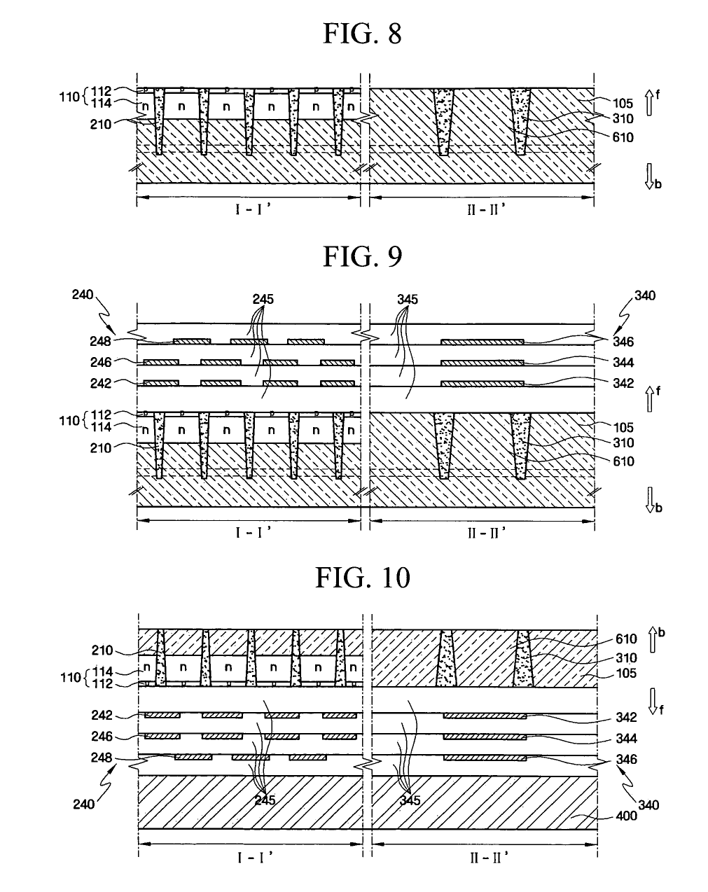

FIG. 4 is an enlarged layout view of an example area “b” in a pad region of the image sensor of FIG. 2, according to an embodiment of the present invention. FIG. 5 is a cross-sectional view of the image sensor taken along line I-I′ of FIG. 3B and line II-II′ of FIG. 4, according to an embodiment of the present invention.

Referring to FIG. 2, a pixel region A is defined in a central area of the single IC chip for implementing the exemplary image sensor. A pad region B is defined in a peripheral area around the pixel region A. Referring to FIGS. 2 and 3A, the pixel region A includes an active pixel sensor (APS) array with a plurality of unit pixels 100 arranged in a matrix form. Referring to FIGS. 2 and 4, the pad region B includes multiple pads 620 for inputting/outputting various signals or voltages.

Referring to FIGS. 3A and 3B, the unit pixel 100 includes a photoelectric converter 110, a charge detector 120, a charge transfer unit 130, a reset unit 140, an amplifier 150, and/or a selector 160. As shown in the example of FIG. 3A, the unit pixel 100 may include four or more transistors.

The photoelectric converter 110 generates and accumulates an amount of charge corresponding to intensity of received light. The photoelectric converter 110 may be a photodiode, a photo transistor, a photo gate, a PPD (pinned photodiode), or a combination thereof.

The charge detector 120 is a floating diffusion region (FD) in an example embodiment of the present invention. The FD node 120 receives the charge accumulated by the photoelectric converter 110. The FD node 120 with parasitic capacitance accumulates the transferred charge from the photoelectric converter 110. The FD node 120 is electrically connected to a gate of the amplifier 150 for control of the amplifier 150.

The charge transfer unit 130 transfers charge from the photoelectric converter 110 to the charge detector 120. In the example embodiment of FIG. 3A, the charge transfer unit 130 is one field effect transistor that is controlled by a charge-transfer signal TG.

The reset unit 140 periodically resets the FD node 120, and the reset unit 140 is a field effect transistor in FIG. 3A. A source of the reset unit 140 is connected to the FD node 140, and a drain of the reset unit 140 is connected to a power voltage supply Vdd. The reset unit 140 is driven in response to a reset signal RST.

In the example of FIG. 3A, the amplifier 150 is a field effect transistor configured as a source follower buffer amplifier biased with a constant current source (not shown) that is outside the unit pixel 100. In that case, a voltage varying in response to the voltage at the FD node 120 is generated at a vertical signal line 162. A drain of the amplifier 150 is connected to the power voltage supply Vdd, and a source of the amplifier 150 is connected to a drain of the selector 160 that is a field effect transistor in FIG. 3A.

The selector 160 selects a row of unit pixels 100 to be read. The selector 160 is driven in response to a selection signal. A source of the selector 160 is connected to the vertical signal line 162.

Driving signal lines 131, 141, and/or 161 of the charge transfer unit 130, the reset unit 140, and/or the selector 160 extend in a row direction (shown as horizontal in FIG. 3A) such that the unit pixels of the same row are simultaneously driven. Referring to FIG. 4, the pad 620 is formed in the pad region B and is insulated from the peripheral area by an insulation layer 310 surrounding the pad 620.

The image sensor according to an embodiment of the present invention is now described in reference to FIG. 5 showing a cross-sectional view of the pixel region A taken along line I-I′ of FIG. 3B and the pad region B taken along line II-II′ of FIG. 4. Referring to FIG. 5, the image sensor has integrated circuit structures such as dielectric layers 245 and 345 formed on a front-side of a circuit substrate 105.

The circuit substrate 105 may be various types of substrates such as a P-type or N-type bulk substrate, a P-type or N-type epitaxial layer formed on the P-type or N-type bulk substrate, or an organic plastic substrate. The circuit substrate 105 shown in FIG. 5 is a substrate formed by completely removing the bulk substrate by polishing to leave only the epitaxial layer. However, the present invention is not limited thereto such that the bulk substrate may also remain.

First, second, and third level interconnects (i.e., wirings) 242, 246, and 248 are formed through dielectric layers 245 over the front-side of the circuit substrate 105 in the pixel region A. First, second, and third level interconnects (i.e., wirings) 342, 346, and 348 are formed through dielectric layers 345 over the front-side of the circuit substrate 105 in the pad region B. The first layer wiring 342 is formed closest to the front-side of the circuit substrate 105 in the pad region B and contacts a conductive contact 622.

A support substrate 400 is bonded from the dielectric layer 245 farthest from the front-side of the circuit substrate 105. The support substrate 400 provides structural support for the circuit substrate 105 that is thinned by polishing. The support substrate 400 may be a generally used semiconductor substrate, such as a wafer. Alternatively, any other material that maintains mechanical strength of the circuit substrate 105 may be used for the support substrate 400 such as a glass substrate.

In pixel region A, a plurality of isolation regions 210 are formed to extend through the circuit substrate 105 from the front-side to a back-side of the circuit substrate 105, as illustrated in FIG. 5. However, the present invention may be practiced with the isolation regions 210 extending partially or completely through the circuit substrate 105.

In addition, the present invention may also be practiced with some of the isolation regions 210 extending partially through the circuit substrate 105, and some of the isolation regions 210 extending completely through the circuit substrate 105. Here, the phrase “extending partially through the circuit substrate 105” means being formed from the front-side of the circuit substrate 105 to an intermediate depth before reaching the back-side of the circuit substrate 105 along the depth of the circuit substrate 105.

Each of the isolation regions 210 is formed by filling a trench formed into the circuit substrate 105 with an insulating material such as an oxide. The isolation regions 210 become narrower from the front-side to the back-side of the circuit substrate 105. The isolation regions 210 may be formed as STI (Shallow Trench Isolation) regions or DTI (Deep Trench Isolation) regions. When the isolation regions 210 are DTI regions, a depth of the isolation regions 210 is greater than that of each of the photoelectric converters 110.

Each of the photoelectric converters 110 is electrically isolated from each-other by the isolation regions 210. The photoelectric converters 110 are formed in regions of the circuit substrate 105 separated by the isolation regions 210. Each photoelectric converter 110 includes a respective P+ type pinning layer 112 and a respective N-type photodiode region 114. The pinning layer 112 reduces or prevents thermally generated EHPs (Electron-Hole Pairs) from reaching a surface of the circuit substrate 105.

The photodiode region 114 has a maximum doping concentration in a range of from about 1×10E15 atoms/cm³ to about 1×10E18 atoms/cm³ in an example embodiment of the present invention. The pinning layer 112 has a maximum doping concentration in a range of from about 1×10E17 atoms/cm³ to about 1×10E20 atoms/cm³ in an example embodiment of the present invention. However, the present invention is not limited to any doping concentrations, depth, or any other numerical values mentioned herein.

FIG. 5 shows the photodiode region 114 formed in only a part of the circuit substrate 105. However, the present invention may also be practiced with the photodiode 114 being formed in a majority portion of the circuit substrate 105. In addition, other doped regions (not shown) may also be formed below the photodiode region 114 toward the back-side of the circuit substrate 105 to promote charge accumulation in the photodiode region 114.

In the pad region B, a ring-shaped insulation layer 310 is formed to extend through the circuit substrate 105. As shown in FIG. 4, the insulation layer 310 is a rectangular ring for example. Alternatively, the insulation layer 310 may be a circular ring or a polygonal ring. In addition, the insulation layer 310 narrows from the front-side to the back-side of the circuit substrate 105. Another words, a transverse cross-sectional area (i.e., the area formed into the page of FIG. 5) of the insulation layer 310 decreases from the front-side to the back-side of the circuit substrate 105.

The insulation layer 310 is formed to a same level as the isolation regions 210 along the depth from the front-side to the back-side of the circuit substrate 105 in on embodiment of the present invention. In the example of FIG. 5, the insulation layer 310 and the isolation regions 210 are formed to completely extend from the front-side to the back-side of the circuit substrate 105 along the depth of the circuit substrate 105.

Further referring to FIG. 5, a contact opening 610 is formed to expose the first layer interconnect 342. The contact opening 610 is formed to extend through a portion of the substrate 105 surrounded by the insulation layer 310. In addition, the contact opening 610 is also formed through the dielectric layer 345 closest to the front-side of the circuit substrate 105.

The conductive contact 622 is formed at walls of the opening 610 to connect the first layer interconnect 342 with a conductive pad 620 formed over the backside of the circuit substrate 105. Referring to FIG. 5, a portion (having the same shading as the circuit substrate 105) of the circuit substrate 105 remains between the insulation layer 310 and the conductive contact 622.

Also referring to FIG. 5, an anti-reflection layer 510 and a buffer layer 520 are formed on the backside of the circuit substrate 105. The material and thickness of the anti-reflection layer 510 depends on the wavelength of light used during photolithography. For example, stacked layers of about 50-200 Å thick silicon oxide film and about 300-500 Å thick silicon nitride film form the anti-reflection film 510 in an example embodiment of the present invention.

The buffer layer 520 is formed on the anti-reflection layer 510. The buffer layer 520 prevents the substrate 105 from being damaged during a patterning process for forming the pad 620. For example, the buffer layer 520 is comprised of a silicon oxide film having a thickness in a range of about 3000-8000 Å in an example embodiment of the present invention.

In the image sensor of FIG. 5, the contact 622 and the pad 620 are effectively insulated from the circuit substrate 105 with the insulation layer 310. Accordingly, the circuit substrate 105 is electrically isolated from the contact 622 and the pad 620 without separately forming spacers, or other elements, with improved stability of the image sensor. Alternatively, the present invention may also be practiced with spacers (not shown) also formed on sidewalls of the opening 610.

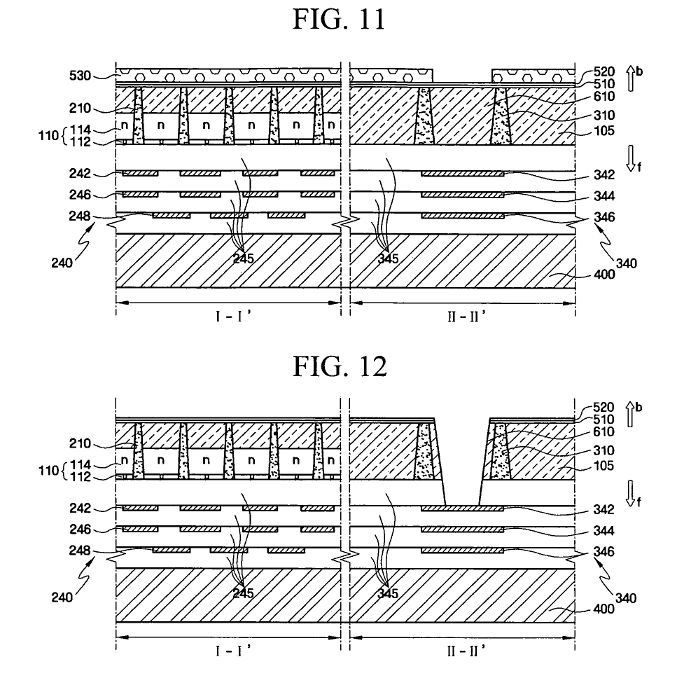

Hereinafter, a method of manufacturing the image sensor of FIG. 5 is now described in reference to FIGS. 6, 7, 8, 9, 10, 11, and 12, according to an embodiment of the present invention. FIGS. 6, 7, 8, 9, 10, 11, and 12 are cross-sectional views along line I-I′ in the pixel region A of FIG. 3B and line II-II′ in the pad region of FIG. 4 during fabrication of the image sensor of FIG. 5, according to an embodiment of the present invention.

Referring to FIG. 6, the circuit substrate 105 may be a silicon substrate, SOI (silicon on insulator), a gallium-arsenide (Ga—As) substrate, a silicon-germanium (Si—Ge) substrate, a ceramic substrate, a quartz substrate, or a glass substrate for a display device. Referring to FIG. 7, the isolation regions 210 are formed in the pixel region A of the circuit substrate 105, and the insulation layer 310 is formed as a ring in the pad region B of the circuit substrate 105.

Here, the isolation regions 210 are STI or DTI regions in an embodiment of the present invention. FIG. 7 shows the isolation regions 210 formed as DTI regions sufficiently deep into the circuit substrate 105. However, the present invention is not limited to the illustrated example. In the example of FIG. 7, the insulation layer 310 is formed as a ring with a central portion of the circuit substrate 105 being surrounded by the insulation layer 310.

However, the present invention may also be practiced with the insulation layer 310 being formed not as a ring such that a central portion of the circuit substrate 105 is not formed. In that case, the insulation layer 310 would be shown as one structure in the cross-sectional view of FIG. 7.

The insulation layer 310 and the isolation regions 210 are simultaneously formed in an embodiment of the present invention. That is, the insulation layer 310 is formed at the same time as when the isolation regions 210 are formed by using a mask pattern over the pixel region A and the pad region B and a photographic etching process for forming the isolation regions 210 and the insulation layer 310. In that case, the depth of the insulation layer 310 and the isolation regions 210 from the front-side of the circuit substrate 105 into the circuit substrate 105 is substantially same.

However, the present invention may also be practiced with a depth of the insulation layer 310 being different from a depth of the isolation regions 210. That is, the insulation layer 310 may be formed to be more deep or more shallow than the isolation regions 210. Since the insulation layer 310 is desired to insulate the contact 622 and the pad 620 from the circuit substrate 105, the insulation layer 310 is formed sufficiently deep such as to a depth in a range of from about 3 μm to about 20 μm.

Further referring to FIG. 7, the isolation regions 210 and the insulation layer 310 become narrower from the front-side toward the back-side along the depth of the circuit substrate 105. Another words, the transverse cross-sectional area (i.e., area into the page of FIG. 7) of the isolation regions 210 and the insulation layer 310 gradually decrease from the front-side toward the back-side along the depth of the circuit substrate 105. Such a narrowing of the isolation regions 210 and the insulation layer 310 is because the amount of etching gas gradually decreases downward into the depth of the substrate 105 during a photographic etching process.

Subsequently referring to FIG. 8, the plurality of photoelectric converters 110 are formed in exposed portions of the pixel region A of the circuit substrate 105. Each photoelectric converter 110 is formed to be electrically isolated by the isolation regions 210. Each photoelectric converter 110 is formed to include a P+ type pinning layer 112 formed by ion implantation and an N-type photodiode region 114 formed by ion implantation. Thus, each photoelectric converter 110 is a pinned photodiode.

FIG. 8 shows the photoelectric converters 110 being shallower than the isolation regions 210. However, the present invention is not limited thereto. Nevertheless, if the isolation regions 210 are formed by DTI, the isolation regions 210 are formed more deeply than the photoelectric converters 110. Furthermore in FIG. 8, deep wells (as indicated by dotted lines in FIG. 8) may also be formed below the photoelectric converters 110 in the circuit substrate 105 for separating a lower region and an upper region of the circuit substrate 105.

Transistors (such as field effect transistors 130, 140, 150, and 160 in FIG. 3B) with the charge detector (such as the FD node 120 of FIG. 3B) for driving the unit pixels are also formed with the circuit substrate 105 along with the photoelectric converters 110.

Thereafter referring to FIG. 9, the integrated circuit structures 240 and 340 including the multi-layer interconnects 242, 244, and 246 in the pixel region A, and the multi-layer interconnects 342, 344, and 346 in the pad region B are formed through the dielectric layers 245 in the pixel region A and 345 in the pad region B. The first layer interconnect 342 is formed closest to the front-side of the circuit substrate 105 in the pad region B.

Subsequently referring to FIG. 10, the support substrate 400 is bonded to the exposed surface of the dielectric layer 245 formed over the entire circuit substrate 105. The support substrate 400 is bonded by forming an adhesive film on a planarized exposed surface of the dielectric layer 245 and forming another adhesive film on an exposed surface of the support substrate 400 that are then joined together, in an example embodiment of the present invention.

Next in FIG. 10, the back-side of the circuit substrate 105 is ground such as by CMP (Chemical Mechanical Polishing), BGR (Back Grinding), RIE (Reactive Ion Etching), or a combination thereof. A thickness of a remaining portion of the circuit substrate 105 after the grinding is in a range of from about 3 μm to about 20 μm. The grinding of the backside of the circuit substrate 105 is performed until the insulation layer 310 is exposed at the back-side of the circuit substrate 105. In that case, the present invention may be practiced with the isolation regions 210 being exposed or not being exposed.

Subsequently referring to FIG. 11, the anti-reflection layer 510 and the buffer layer 520 are formed on the back-side of the polished circuit substrate 105. The anti-reflection layer 510 in an example embodiment is comprised of a stack of about 50-200 Å thick silicon oxide film and about 300-500 Å thick silicon nitride film deposited from CVD (Chemical Vapor Deposition) for example. The buffer layer 520 in an example embodiment is comprised of a stack of a silicon oxide film having a thickness in the range of from about 3000 Å to about 8000 Å on the anti-reflection layer 510 from CVD (Chemical Vapor Deposition) for example.

Subsequently in FIG. 11, a hard mask pattern 530 is formed on the buffer layer 520. For example, the hard mask pattern 530 is formed with an opening over a central area of the circuit substrate 105 surrounded by the insulation layer 310. When the insulation layer 310 is ring-shaped, the opening of the hard mask pattern 530 is formed over at least a portion of a central portion of the circuit substrate 105 surrounded by the insulation layer 310. Alternatively when the insulation layer 310 is not formed as a ring, the opening of the hard mask pattern 530 is formed over a central portion of the insulation layer 310.

Thereafter referring to FIG. 12, the contact opening 610 is formed using the hard mask pattern 530 as an etch mask. Thus, the contact opening 610 is formed to extend through a portion of the substrate 105 under the opening 610 along the depth of the substrate 105 and a portion of the dielectric layer 345 under the opening 610 until the first layer interconnect 342 is exposed. In the example FIG. 12, a portion of the circuit substrate 105 remains at the sidewalls of the contact opening 610.

The contact opening 610 may be formed by anisotropic etching. In the case that the insulation layer 310 is not formed as a ring, the contact opening 610 would be formed to extend through a central portion of the insulation layer 310 and a portion of the dielectric layer 345 under the opening 610 until the first layer interconnect 342 is exposed.

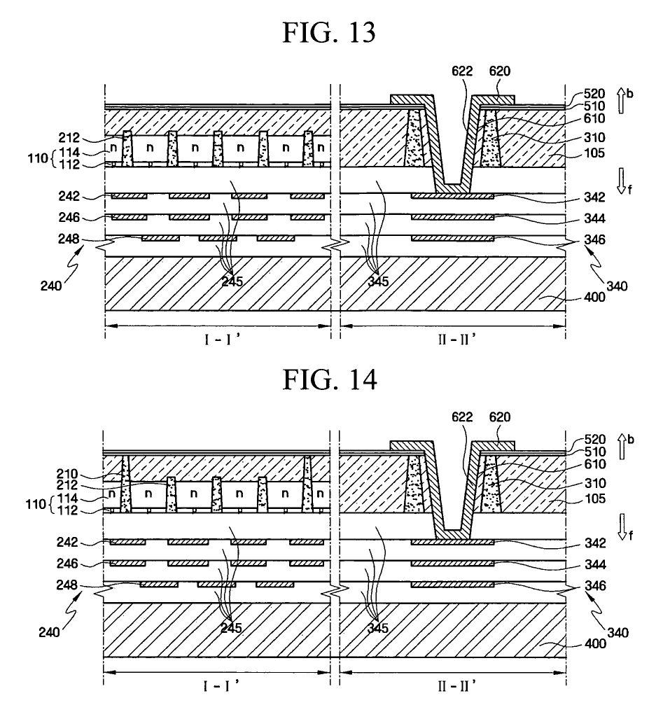

Subsequently referring to FIG. 13, a conductive material (not shown) is conformally deposited on exposed surfaces of the buffer layer 520 and the opening 610, and then patterned to form the conductive contact 622 and the conductive pad 620. The conductive contact 622 is formed at exposed walls of the opening 610, and the conductive pad 620 is formed at a portion of the buffer layer 520 to be connected to the contact 622. Thus, the contact 622 electrically connects the pad 620 with the first layer interconnect 342.

While FIG. 13 shows the contact 622 and the pad 620 formed as an integral structure from the conformally deposited conductive material, the invention is not limited thereto. The present invention may also be practiced with the contact 622 and the pad 620 being formed with separate processes. In the embodiment of FIG. 13, a portion (having a same cross-sectional shading as the circuit substrate 105) of the circuit substrate 105 remains between the contact 622 and the insulation layer 310.

Nevertheless, the insulation layer 310 surrounds the contact 622 to electrically isolate the contact 622 from the rest of the circuit substrate 105. In addition, the dielectric layer 345 closest to the front-side of the circuit substrate 105 surround a bottom portion of the contact 622. A bottom surface of the contact 622 contacts the first layer interconnect 342.

In this manner, with simultaneous formation of the isolation regions 210 and the insulation layer 310, isolation of the photoelectric converters 110 and insulation of the contact 622 and the pad 620 may be achieved without additional processes. In addition, for ensuring insulation of the contact 622 and the pad 620, spacers (not shown) may also be formed on sidewalls of the contact opening 610. Accordingly, the image sensor with improved stability and efficient manufacturability may be fabricated.

Hereinafter, image sensors according to other embodiments of the present invention are now described with reference to FIGS. 13, 14, and 15. Elements having the same reference number in FIGS. 5, 6, 7, 8, 9, 10, 11, 12, 13, 14, and 15 refer to elements having similar structure and/or function such that a detailed description thereof is not repeated.

Comparing FIGS. 5 and 13, the image sensor of FIG. 13 includes isolation regions 212 that do not completely extend through the circuit substrate 105. That is, the isolation regions 212 are not exposed at the back-side of the circuit substrate 105. FIG. 13 shows the isolation regions 212 being formed deeper than the photoelectric converters 110. Alternatively, the depths of the isolation regions 212 may be shallower than those of the photoelectric converters 110.

Comparing FIGS. 5 and 14, the image sensor of FIG. 14 includes some isolation regions 212 that do not completely extend through the circuit substrate 105. The image sensor of FIG. 15 also includes some isolation regions 210 that do completely extend through the circuit substrate 105. That is, the isolation regions 210 and 202 have different depths from the front-side of the circuit substrate 105.

Comparing FIGS. 5 and 15, the image sensor of FIG. 15 includes the contact opening 610 formed to extend through an insulation layer 312 such that the contact abuts the insulation layer 312 at the sidewalls of the opening 610. Such a structure of FIG. 15 may be attained by increasing the width of the contact opening 610 for exposing the insulation layer 310 at sidewalls of the contact opening 610. Alternatively such a structure of FIG. 15 maybe be attained by forming the insulation layer 310 not as a ring but as one region such that when the contact opening 610 is etched through a central portion of the insulation layer 310, the material of the insulation layer 310 is exposed at the sidewalls of the opening 610.

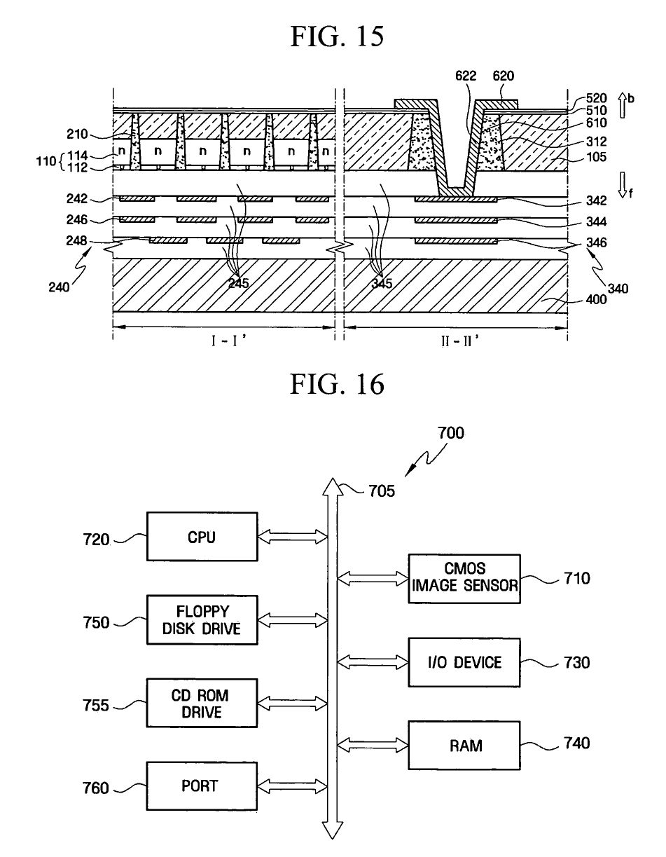

FIG. 16 shows a block diagram of a processor-based system 700 including a CMOS image sensor 710 implemented similarly as the image sensor of FIGS. 1, 2, 3A, 3B, 4, 5, 6, 7, 8, 9, 10, 11, 12, 13, 14, and/or 15, according to an embodiment of the present invention.

Referring to FIG. 16, the processor-based system 700 processes electrical signals generated by the CMOS image sensor 710 to capture an image. The system 700 may be a computer system, a camera system, a scanner, a mechanized clock system, a navigation system, a video phone, a directing system, an auto-focusing system, a tracking system, a movement monitoring system, or an image stabilization system, but the system 700 is not limited thereto.

The processor-based system 700 such as a computer includes a central processing unit (CPU) 720 such as a microprocessor that communicates with an input/output (I/O) element 730 through a bus 705. The CMOS image sensor 710 communicates with the other components of the system 700 through the bus 705 or any other communication link.

The processor-based system 700 further includes a random access memory (RAM) 740, a floppy disk drive 750 and/or a CD ROM drive 755, and a port 760 which allows the system 700 to communicate with the CPU 720 through the bus 705. A video card, a sound card, a memory card, or a USB element is coupled to the port 760, or the port 760 allows the system 700 to communicate data to another system. The CMOS image sensor 710 may be integrated with a CPU, a digital signal processing device (DSP), or a microprocessor. Also, the CMOS image sensor 710 may be integrated with a memory. Alternatively, the CMOS image sensor 710 is integrated on a chip, separate from a processor.

While the present invention has been particularly shown and described with reference to an exemplary embodiment thereof, it will be understood by those of ordinary skill in the art that various changes in form and details may be made therein without departing from the spirit and scope of the present invention as defined by the following claims.

The present invention is limited only as defined in the following claims and equivalents thereof.

What is claimed is:

1. An image sensor comprising:
a circuit substrate having a pixel region and a pad region;
a plurality of isolation regions formed in the pixel region;
a plurality of photoelectric converters formed in the pixel region, each photoelectric converter being electrically isolated by the plurality of isolation regions; and
an insulation layer formed in the pad region, wherein the plurality of isolation regions and the insulation layer extend into the circuit substrate with a substantially same depth.

2. The image sensor of claim 1, further comprising:
a support substrate disposed to face a front-side of the circuit substrate, wherein the photoelectric converters are formed into the front-side of the circuit substrate.

3. The image sensor of claim 2, further comprising:
a plurality of interconnects and a plurality of dielectric layers disposed between the front-side of the circuit substrate and the support substrate.

4. The image sensor of claim 3, further comprising:
an opening formed through the insulation layer and a first dielectric layer to abut a first layer interconnect;
a conductive contact formed at walls of the opening; and
a conductive pad formed over a back-side of the circuit substrate and connected to the conductive contact.

5. The image sensor of claim 4, wherein the isolation regions and the opening become narrower from the front-side to the back-side of the circuit substrate.

6. The image sensor of claim 4, wherein the insulation layer surrounds at least a portion of the opening.

7. The image sensor of claim 6, wherein one of the dielectric layers surrounds at least a remaining portion of the opening not surrounded by the insulation layer.

8. The image sensor of claim 6, further comprising:
a substrate material of the circuit substrate disposed between the conductive contact and the insulation layer.

9. The image sensor of claim 1, wherein the isolation regions and the insulation layer extend completely through the circuit substrate.

10. The image sensor of claim 1, wherein each photoelectric converter is a pinned photodiode formed from a front-side of the circuit substrate.

11. An image sensor, comprising:
a circuit substrate having a pixel region and a pad region;
a plurality of isolation regions formed in the pixel region;
a plurality of photoelectric converters formed in the pixel region, each photoelectric converter being electrically isolated by the plurality of isolation regions;
an opening formed through the circuit substrate in the pad region;
an insulation layer that surrounds at least a portion of the opening in the pad region;
a conductive contact formed at walls of the opening; and
a substrate material of the circuit substrate disposed between the conductive contact and the insulation layer.

12. The image sensor of claim 11, wherein the plurality of isolation regions and the insulation layer extend into the circuit substrate with a substantially same depth.

13. The image sensor of claim 11, further comprising:
a support substrate disposed to face a front-side of the circuit substrate, wherein the photoelectric converters are formed into the front-side of the circuit substrate.

14. The image sensor of claim 13, further comprising:
a plurality of interconnects and a plurality of dielectric layers disposed between the front-side of the circuit substrate and the support substrate.

15. The image sensor of claim 14, wherein the opening is formed through the insulation layer and a first dielectric layer to abut a first layer interconnect.

16. The image sensor of claim 15, wherein one of the dielectric layers surrounds at least a remaining portion of the opening not surrounded by the insulation layer.

17. The image sensor of claim 11, further comprising:
a conductive pad formed over a back-side of the circuit substrate and connected to the conductive contact.

18. The image sensor of claim 11, wherein the isolation regions and the opening become narrower from the front-side to the back-side of the circuit substrate.

19. The image sensor of claim 11, wherein the isolation regions and the insulation layer extend completely through the circuit substrate.

20. The image sensor of claim 11, wherein each photoelectric converter is a pinned photodiode formed from a front-side of the circuit substrate.
